(19) United States
(12) Patent Application Publication
(10) Pub. No.: US 2023/0062685 A1
(43) Pub. Date: Mar. 2, 2023

(54) VARAIABLE FOCAL LENGTH OPTICAL ELEMENT

(71) Applicant: Coretronic MEMS Corporation, MIAOLI COUNTY (TW)

(72) Inventors: Mei-Ling Chen, Miaoli County (TW); Ming-Ching Wu, Miaoli County (TW)

(73) Assignee: Coretronic MEMS Corporation, MIAOLI COUNTY (TW)

(21) Appl. No.: 17/896,027

(22) Filed: Aug. 25, 2022

(30) Foreign Application Priority Data
Sep. 1, 2021 (TW) 110132399

(51) Int. Cl. G02B 3/14; G02B 26/08; H01L 41/09

(52) U.S. Cl. CPC G02B 3/14; G02B 26/0825; H01L 41/094

(57) ABSTRACT

A variable focal length optical element including a light-transmitting layer, a cover, a gel, a piezoelectric film, and a driving electrode is provided. The cover has a first through hole to define a light-passing area. The cover, an adhesive layer, and the light-transmitting layer surround and form a first cavity together, and the gel is filled in the first cavity. The driving electrode is configured to drive the piezoelectric film, so that the piezoelectric film is deformed to pull the light-transmitting layer to bend and deform to squeeze the gel in the first cavity, and thereby controls a curvature change of an optical surface formed in the light-passing area by the gel protruding out from the first through hole.

### CROSS-REFERENCE TO RELATED APPLICATION

This application claims the priority benefit of Taiwan application serial no. 110132399, filed on Sep. 1, 2021. The entirety of the above-mentioned patent application is hereby incorporated by reference herein and made a part of this specification.

### BACKGROUND

### Technical Field

The disclosure relates to an optical element, and in particularly, relates to a variable focal length optical element.

### Description of Related Art

Optical elements with zooming capability have been widely used in various optical systems, such as imaging optics with autofocus, adaptive optical systems, light switches, virtual reality (VR), or augmented reality (AR) wearable display devices, etc. Commonly used variable focal length optical elements may be divided into two types according to principles thereof. The first type of variable focal length optical elements uses the relative distance change between the lenses in the optical axis direction to achieve the zooming function, and the second type of variable focal length optical elements have deformable optical lenses.

To be specific, at least one lens of the first type of variable focal length optical elements requires an external linear driving device to change the relative distance of the lenses to achieve the purpose of optical zooming. Therefore, the first type of variable focal length optical elements has disadvantages such as larger volume, higher difficulty in precision control, driving noise, etc. On the other hand, the second type of variable focal length optical elements uses a deformable optical lens and does not require a linear driving unit, so that it has advantages of small size, high precision, fast response speed, silent operation, etc. Among the variable focal length optical elements with deformable optical lenses, the variable focal length optical elements driven by the piezoelectric effect have a response rate of more than tens of thousands of hertz (kHz), and may be produced by using the same manufacturing process of the micro electro mechanical system (MEMS). In this way, the structures of the variable focal length optical elements may be further miniaturized, mass production may also be achieved, and a wide range of commercial applications are therefore provided.

The information disclosed in this BACKGROUND section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the invention was acknowledged by a person of ordinary skill in the art.

### SUMMARY

The disclosure is directed to a variable focal length optical element exhibiting a simple manufacturing process and stable optical characteristics.

Other objects and advantages of the disclosure may be further illustrated by the technical features broadly embodied and described as follows.

In order to achieve one or a portion of or all of the objects or other objects, an embodiment of the disclosure provides a variable focal length optical element. The variable focal length optical element includes a light-transmitting layer, a cover, a gel, a piezoelectric film, and a driving electrode. The cover has a first through hole to define a light-passing area, and the cover is adhered to the light-transmitting layer via an adhesive layer. The cover, the adhesive layer, and the light-transmitting layer surround and form a first cavity together. The gel is filled in the first cavity. The light-transmitting layer is disposed in overlap with the piezoelectric film. The driving electrode is configured to drive the piezoelectric film. The driving electrode applies a driving voltage to the piezoelectric film, so that the piezoelectric film is stretched and deformed to pull the light-transmitting layer to bend and deform to squeeze the gel in the first cavity, and thereby controls a curvature change of an optical surface formed in the light-passing area by the gel protruding out from the first through hole.

Based on the above description, the embodiments of the disclosure have at least one of the following advantages or effects. In the embodiments of the disclosure, the variable focal length optical element may adopt a predetermined driving voltage for applying to the piezoelectric film to cause the piezoelectric film to generate stress deformation, thereby squeezing the gel in the first cavity and accordingly controlling the curvature change of the optical surface formed by the gel in the light-passing area, so that the variable focal length optical element may easily achieve a purpose of controlling optical zooming.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic cross-sectional view of a variable focal length optical element according to an embodiment of the disclosure.

FIG. 1B is a schematic top view of the variable focal length optical element of FIG. 1A.

FIG. 1C is a schematic cross-sectional view of the variable focal length optical element of FIG. 1A deformed by applying a driving voltage.

FIG. 1D is a data curve diagram of a profile change of a light-transmitting layer of FIG. 1A when different driving voltages are applied.

FIG. 2 to FIG. 5 are schematic cross-sectional views of other variable focal length optical elements according to other different embodiments of the disclosure.

### DESCRIPTION OF THE EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

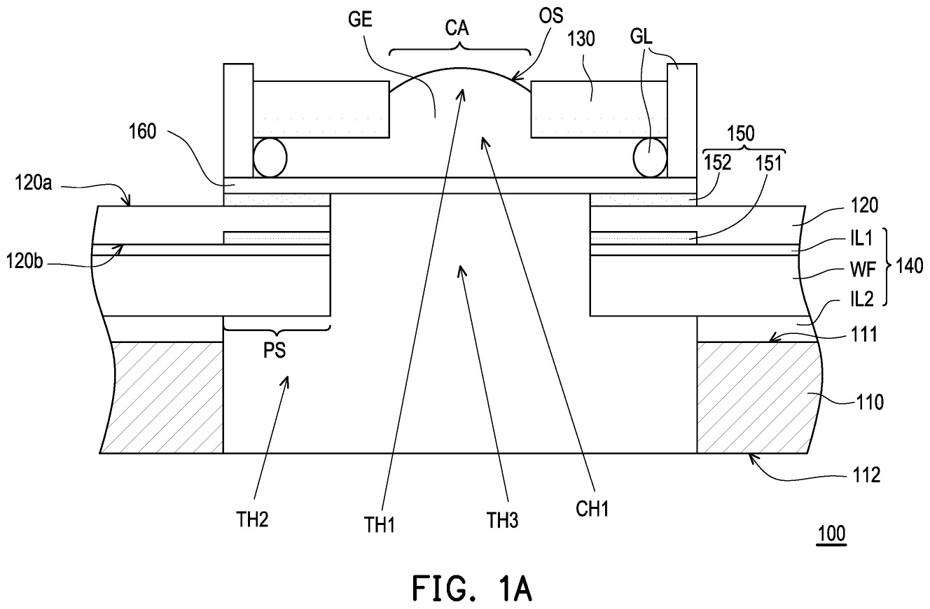

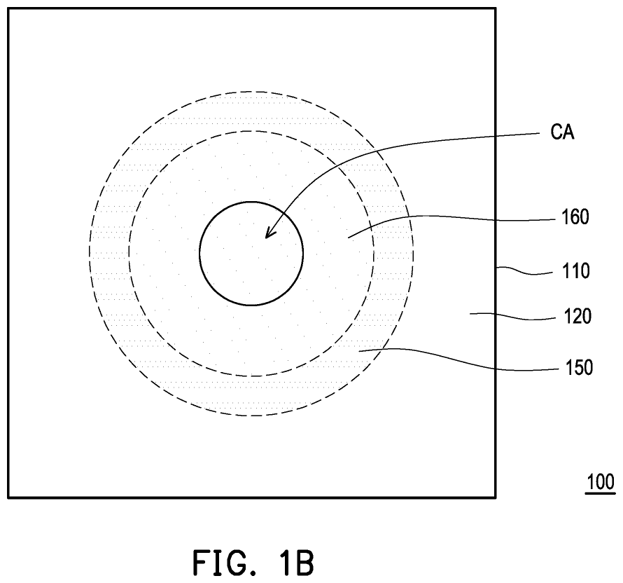

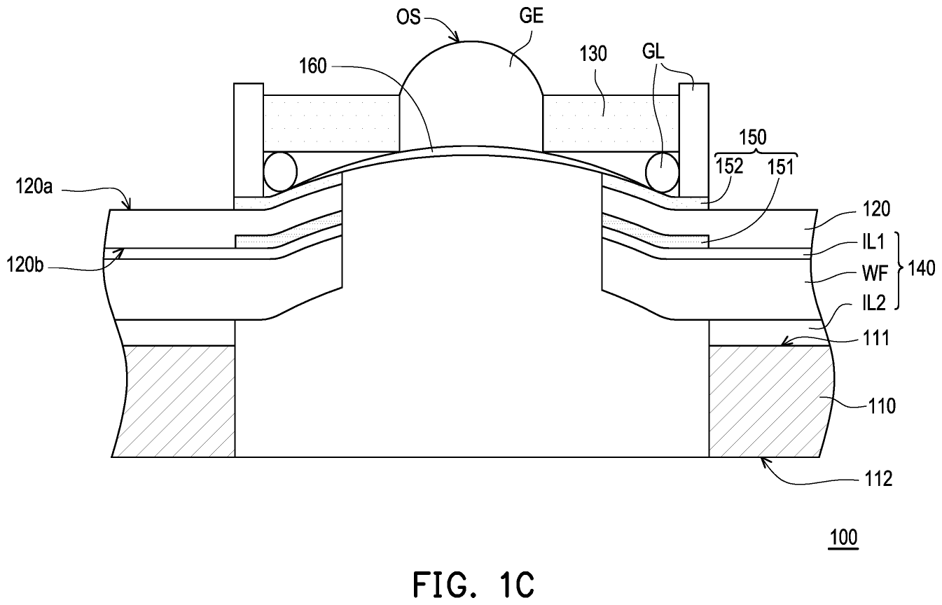

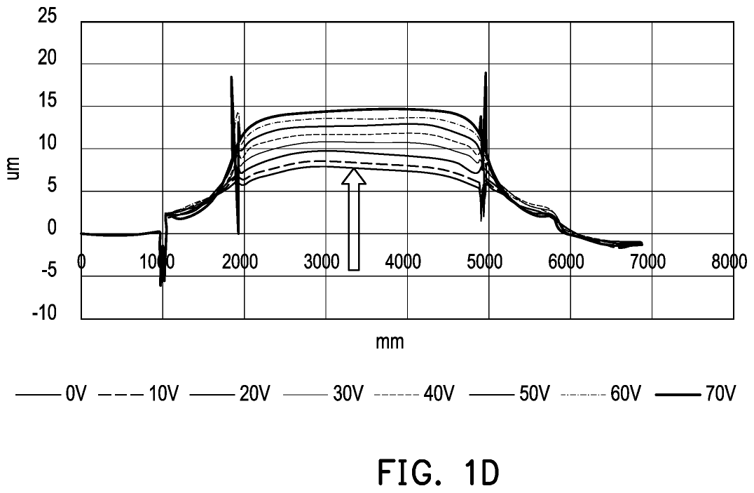

FIG. 1A is a schematic cross-sectional view of a variable focal length optical element according to an embodiment of the disclosure. FIG. 1B is a schematic top view of the variable focal length optical element of FIG. 1A. FIG. 1C is a schematic cross-sectional view of the variable focal length optical element of FIG. 1A deformed by applying a driving voltage. FIG. 1D is a data curve diagram of a profile change of a light-transmitting layer of FIG. 1A when different driving voltages are applied. With reference to FIG. 1A, the variable focal length optical element 100 of this embodiment includes a first substrate 110, a piezoelectric film 120, a cover 130, a gel GE, a carrier layer 140, a driving electrode 150, and a light-transmitting layer 160. It should be noted that, in order to highlight important technical features of the disclosure, the drawings are only schematic diagrams, and are not drawn to scale. In the embodiment, a material of the first substrate 110 is, for example, silicon, but the disclosure is not limited thereto. In the embodiment, the piezoelectric film 120 is made of a light-transmitting material, such as a piezoelectric film made of single crystal, but the disclosure is not limited thereto. In other embodiments, the piezoelectric film 120 may be made of a non-light-transmitting material. In addition, in this embodiment, a material of the light-transmitting layer 160 includes a polymer material or glass.

To be specific, as shown in FIG. 1A, in the embodiment, the first substrate 110 has a first surface 111 and a second surface 112 opposite to each other. The carrier layer 140 is located on the first surface 111 of the first substrate 110. The carrier layer 140 includes a first insulating layer IL1, a second insulating layer IL2, and a wafer layer WF. The second insulating layer IL2 is disposed in overlap with the first insulating layer IL1. The wafer layer WF is located between the first insulating layer IL1 and the second insulating layer IL2. The piezoelectric film 120 is located on the carrier layer 140. To be specific, the piezoelectric film 120 is disposed on the first insulating layer IL1 of the carrier layer 140, the light-transmitting layer 160 is disposed on the piezoelectric film 120, and the light-transmitting layer 160 is located between the cover 130 and the piezoelectric film 120. For example, in the embodiment, the light-transmitting layer 160 may be grown on the piezoelectric film 120 by an epitaxial method, but the disclosure is not limited thereto. Alternatively, in other embodiments, the light-transmitting layer 160 may also be bonded to the piezoelectric film 120 by an attaching method.

To be specific, as shown in FIG. 1A, in the embodiment, the cover 130 has a first through hole TH1 to define a light-passing area CA, and the cover 130 is adhered to the light-transmitting layer 160 via an adhesive layer GL. The cover 130, the adhesive layer GL, and the light-transmitting layer 160 surround and form a first cavity CH1 together. The gel GE is filled in the first cavity CH1. The light-transmitting layer 160 is disposed in overlap with the piezoelectric film 120. The first substrate 110 has a second through hole TH2 penetrating through the first substrate 110. The carrier layer 140 has a third through hole TH3 penetrating through the carrier layer 140. The third through hole TH3 is formed by a protruding structure PS, wherein the protruding structure PS refers to a portion of the carrier layer 140 protruding into the second through hole TH2 of the first substrate 110. The second through hole TH2, the third through hole TH3, and the first through hole TH1 are overlapped with each other, and a projection of the first through hole TH1 on the first substrate 110 is completely located within projections of the second through hole TH2 and the third through hole TH3 on the first substrate 110. In this way, it is ensured that the arrangement of the second through hole TH2 and the third through hole TH3 may not affect the optical performance of the light passing through the light-passing area CA defined by the first through hole TH1.

Next, with reference to FIG. 1A and FIG. 1B, in the embodiment, the driving electrode 150 is configured to drive the piezoelectric film 120. As shown in FIG. 1B, the shape of the driving electrode 150 is annular, and the driving electrode 150 surrounds the light-passing area CA. For example, as shown in FIG. 1A, in the embodiment, the piezoelectric films 120 is respectively clamped by the corresponding driving electrodes 150. The driving electrodes 150 include a first driving electrode 151 and a second driving electrode 152. The first driving electrode 151, the piezoelectric film 120, and the second driving electrode 152 are sequentially stacked on the carrier layer 140 from bottom to top. To be more specific, as shown in FIG. 1A, in the embodiment, the piezoelectric film 120 has an outer surface 120a and an inner surface 120b opposite to each other, wherein the outer surface 120a faces the light-transmitting layer 160, and the inner surface 120b faces the carrier layer 140. The first driving electrode 151 is located between the carrier layer 140 and the inner surface 120b of the piezoelectric film 120. The second driving electrode 152 is located between the outer surface 120a of the piezoelectric film 120 and the light-transmitting layer 160. For example, materials of the first driving electrode 151 and the second driving electrode 152 may be respectively platinum and gold.

Therefore, as shown in FIG. 1C, in this embodiment, when the driving electrode 150 applies a driving voltage to the piezoelectric film 120, the piezoelectric film 120 may be compressed or stretched by an electric field (for example, the piezoelectric film 120 is compressed or stretched in a direction parallel to the first substrate 110). Further, when the driving electrode 150 causes the piezoelectric film 120 to produce stretch deformation, the piezoelectric film 120 directly pulls the light-transmitting layer 160 and the protruding structure PS to bend and deform to squeeze the gel GE in the first cavity CH1, and thereby the driving electrode 150 controls a curvature change of an optical surface OS formed in the light-passing area CA by the gel GE protruding out from the first through hole TH1 and exposed from the cover 130. In this way, the variable focal length optical element 100 may achieve the purpose of optical zooming.

To be specific, in the embodiment, when a certain driving voltage is applied to the driving electrode 150, data of the generated deformation of the light-transmitting layer 160 is simulated and analyzed, and the result is shown in FIG. 1D. Furthermore, in this embodiment, by changing a magnitude of the driving voltage, a deformation amount of the light-transmitting layer 160 driven by the piezoelectric film 120 of the variable focal length optical element 100 may be changed. However, as shown in FIG. 1D, the curvature of a central area of the light-transmitting layer 160 maintains approximately the same, and an arching degree changes only in an edge area. Since the more the light-transmitting layer 160 is arched upward, the more the gel GE in the first cavity CH1 is squeezed, a curvature of the optical surface OS formed by the gel GE protruding out from the first through hole TH1 and exposed from the cover 130 also becomes larger. Therefore, through the control of the driving voltage, the curvature change of the optical surface OS formed in the light-passing area CA may be easily controlled, so that the variable focal length optical element 100 may easily achieve the purpose of controlling optical zooming.

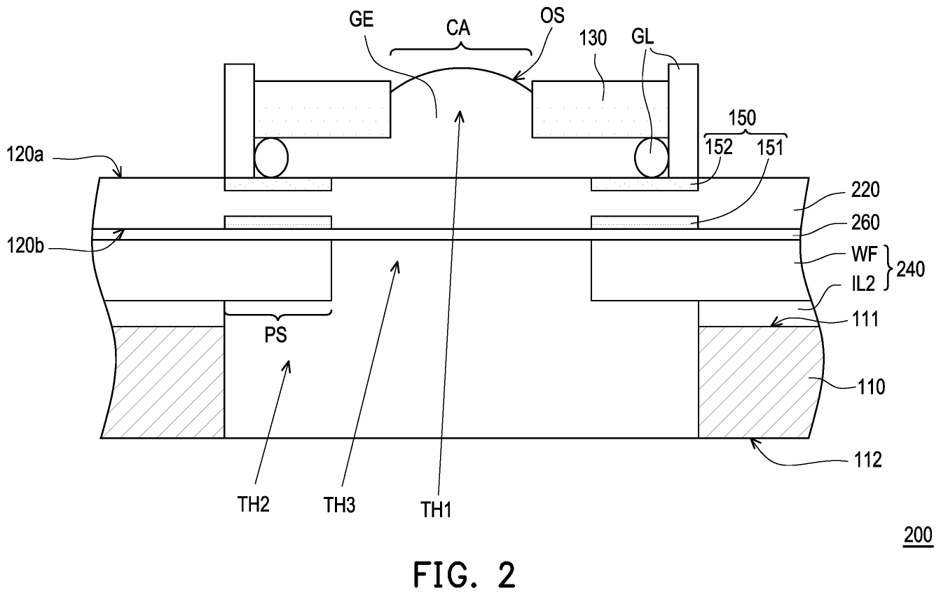

FIG. 2 is a schematic cross-sectional view of another variable focal length optical element according to an embodiment of the disclosure. With reference to FIG. 2, a variable focal length optical element 200 of this embodiment is similar to the variable focal length optical element 100 of FIG. 1A, and a difference there between is as follows. As shown in FIG. 2, in the embodiment, a light-transmitting layer 260 is disposed between a piezoelectric film 220 and a carrier layer 240. For example, the light-transmitting layer 260 may be formed of the first insulating layer IL1 of FIG. 1A, which is made of silicon oxide and has a light-transmitting property, and the carrier layer 240 only includes the second insulating layer IL2 and the wafer layer WF. To be specific, as shown in FIG. 2, in the embodiment, the light-transmitting layer 260 (the first insulating layer IL1) is stacked on the wafer layer WF, and the wafer layer WF is located between the second insulating layer IL2 and the light-transmitting layer 260. In this way, the carrier layer 240 and the light-transmitting layer 260 may be produced by using a process technology of silicon-on-insulator (SOI), which may be integrated with the existing process technology to achieve simple production, but the disclosure is limited thereto. In other embodiments, the carrier layer 240 also includes only the second insulating layer IL2 and the wafer layer WF. The second insulating layer IL2 is located between the first substrate 110 and the wafer layer WF, and the light-transmitting layer 260 is located between the wafer layer WF and the piezoelectric film 220, and the piezoelectric film 220 covers the light-passing area CA. A material of the piezoelectric film 220 may optionally include a polymer material or glass. In addition, as shown in FIG. 2, in this embodiment, the piezoelectric film 220 covers the light-passing area CA.

In this way, the variable focal length optical element 200 of this embodiment may also adopt a predetermined driving voltage for applying to the piezoelectric film 220, so that the piezoelectric film 220 has a stretch stress deformation to squeeze the gel GE in the first cavity CH1, so as to control the curvature change of the optical surface OS formed by the gel GE in the light-passing area CA. In the embodiment, since the variable focal length optical element 200 has a similar structure to the variable focal length optical element 100 and the variable focal length optical element 200 has the same advantages mentioned in the description of the variable focal length optical element 100, description thereof is not repeated.

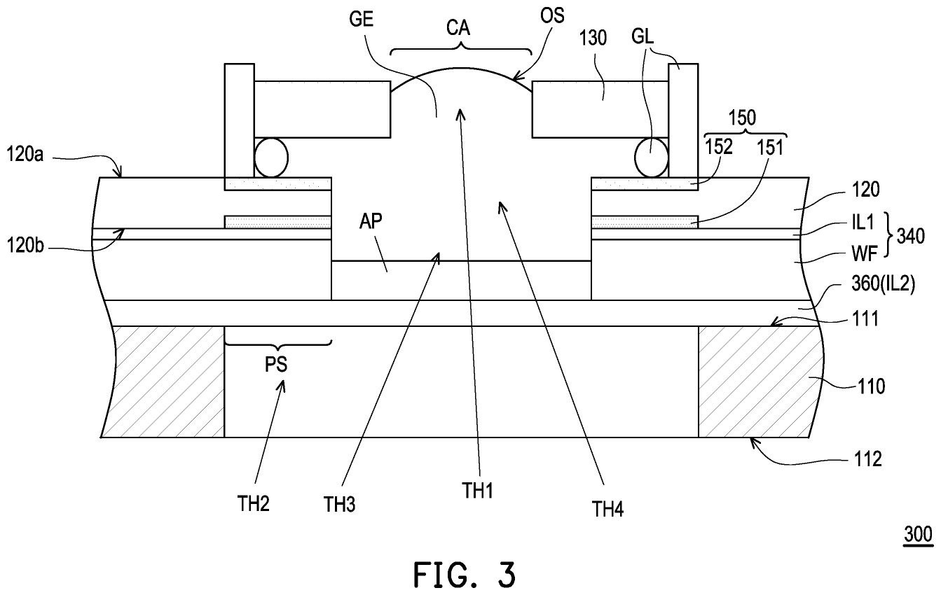

FIG. 3 is a schematic cross-sectional view of another variable focal length optical element according to an embodiment of the disclosure. With reference to FIG. 3, a variable focal length optical element 300 of this embodiment is similar to the variable focal length optical element 100 of FIG. 1A, and a difference there between is as follows. As shown in FIG. 3, in the embodiment, a carrier layer 340 only includes the first insulating layer IL1 and the wafer layer WF. A light-transmitting layer 360 may be formed of the second insulating layer IL2 of FIG. 1A and has a light-transmitting property, and a material thereof is silicon oxide. To be specific, as shown in FIG. 3, the wafer layer WF is located between the first insulating layer IL1 and the light-transmitting layer 360, and the light-transmitting layer 360 is located between the first substrate 110 and the wafer layer WF. In this embodiment, the piezoelectric film 120 is located between the light-transmitting layer 360 and the cover 130. The piezoelectric film 120 has a fourth through hole TH4, and the first cavity CH1 includes the first through hole TH1 of the cover 130, the third through hole TH3 of the carrier layer 340, and the fourth through hole TH4 of the piezoelectric film 120. The variable focal length optical element 300 may optionally further include an auxiliary piezoelectric film AP, wherein the auxiliary piezoelectric film AP is disposed on the light-transmitting layer 360 and may selectively cover only the light-passing area CA to improve stability of the light-transmitting layer 360. The auxiliary piezoelectric film AP may not produce stretch stress deformation due to the driving voltage.

In this way, the variable focal length optical element 300 of this embodiment may also adopt a predetermined driving voltage for applying to the piezoelectric film 120, so that the piezoelectric film 120 has a stretch stress deformation to drive the protruding structure PS of the carrier layer 340 and the light-transmitting layer 360 to deform to squeeze the gel GE in the first cavity CH1, so as to control the curvature change of the optical surface OS formed by the gel GE in the light-passing area CA. In the embodiment, since the variable focal length optical element 300 has a similar structure to the variable focal length optical element 100, the variable focal length optical element 300 has the same advantages mentioned in the description of the variable focal length optical element 100, description thereof is not repeated.

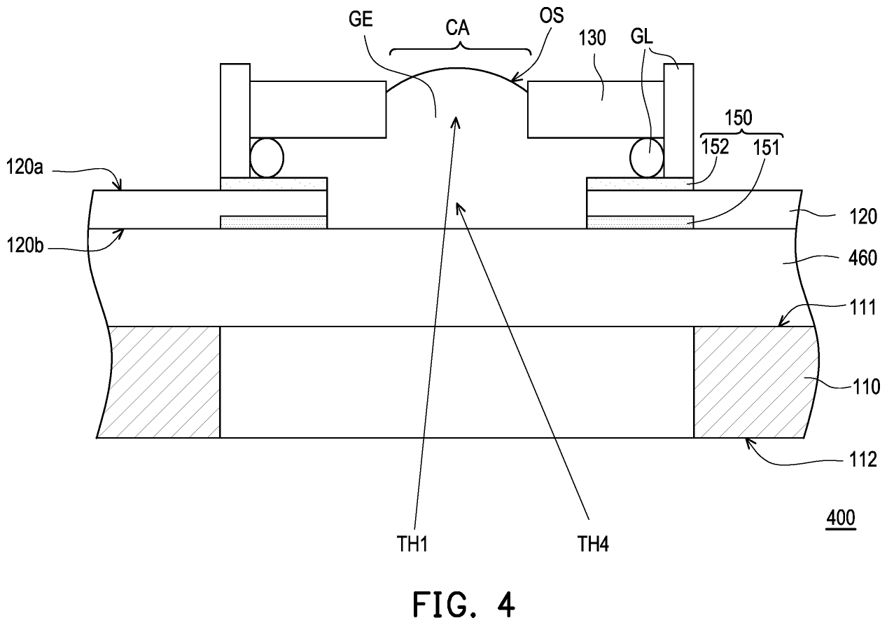

FIG. 4 is a schematic cross-sectional view of another variable focal length optical element according to an embodiment of the disclosure. With reference to FIG. 4, a variable focal length optical element 400 of this embodiment is similar to the variable focal length optical element 100 of FIG. 1A, and a difference there between is as follows. As shown in FIG. 4, in the embodiment, the carrier layer 140 of FIG. 1A is a light-transmitting layer 460 and is formed of an insulating layer, and a material thereof is silicon oxide or glass, wherein the first substrate 110 and the light-transmitting layer 460 may be silicon on glass wafers (SOG wafers). In the embodiment, the protruding structures PS in the light-transmitting layer 460 of the variable focal length optical element 400 that are the same as that of the carrier layer 140 of FIG. 1A may extend toward a center of the light-passing area CA and may be connected to each other without a through hole penetrating through the carrier layer 140. To be specific, as shown in FIG. 4, the light-transmitting layer 460 is located between the first substrate 110 and the piezoelectric film 120, the piezoelectric film 120 has a fourth through hole TH4, and the piezoelectric film 120 is located between the light-transmitting layer 460 and the cover 130. The first cavity CH1 includes the first through hole TH1 of the cover 130 and the fourth through hole TH4 of the piezoelectric film 120.

In this way, the variable focal length optical element 400 of this embodiment may also adopt a predetermined driving voltage for applying to the piezoelectric film 120, so that the piezoelectric film 120 has a stretch stress deformation to drive the light-transmitting layer 460 to deform to squeeze the gel GE in the first cavity CH1, so as to control the curvature change of the optical surface OS formed by the gel GE in the light-passing area CA. In this embodiment, since the variable focal length optical element 400 has a similar structure to the variable focal length optical element 100 and the variable focal length optical element 400 has the same advantages mentioned in the description of the variable focal length optical element 100, description thereof is not repeated.

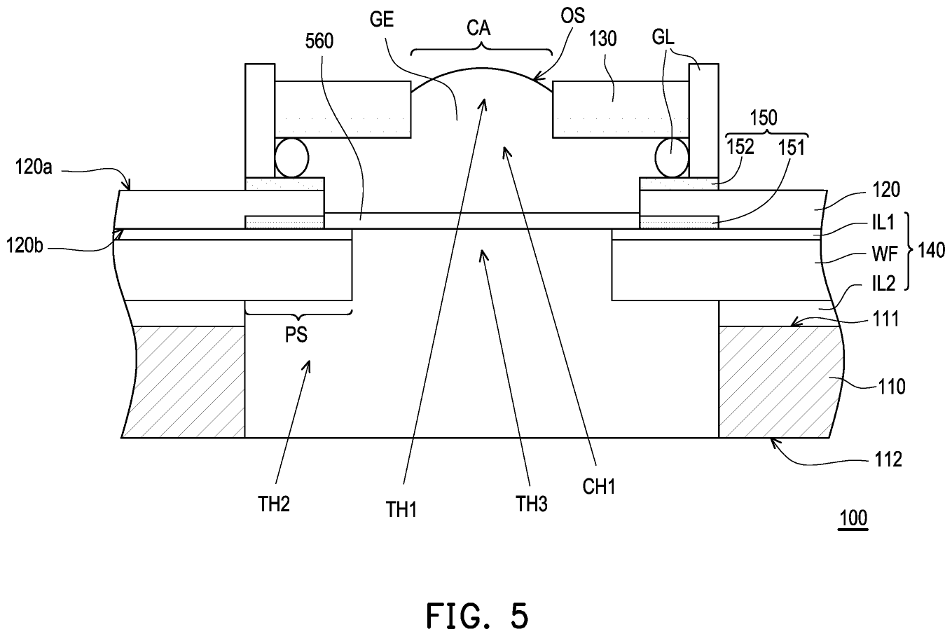

FIG. 5 is a schematic cross-sectional view of another variable focal length optical element according to an embodiment of the disclosure. With reference to FIG. 5, a variable focal length optical element 500 of this embodiment is similar to the variable focal length optical element 100 of FIG. 1A, and a difference there between is as follows. As shown in FIG. 5, in the embodiment, as shown in FIG. 5, in the embodiment, a light-transmitting layer 560 is not disposed in overlap with the piezoelectric film 150, but the light-transmitting layer 560 and the piezoelectric film 150 are all disposed on the first insulating layer IL1 of the protruding structure PS. To be specific, the light-transmitting layer 560 and the piezoelectric film 150 are arranged on a same plane of the first insulating layer IL1 in a coplanar manner, and when the piezoelectric film 150 produces a stretch deformation, the piezoelectric film 150 drives the protruding structure PS of the carrier layer 140 and indirectly pulls the light-transmitting layer 560 to bend and deform. Accordingly, the gel GE in the first cavity CH1 is squeezed to control the curvature change of the optical surface OS formed by the gel GE in the light-passing area CA. In the embodiment, since the variable focal length optical element 500 and the variable focal length optical element 100 have a similar structure and the variable focal length optical element 500 has the same advantages mentioned in the description of the variable focal length optical element 100, description thereof is not repeated.

In view of the foregoing, the embodiments of the disclosure have at least one of the following advantages or effects. In the embodiments of the disclosure, the variable focal length optical element may adopt a predetermined driving voltage for applying to the piezoelectric film to cause the piezoelectric film to generate stress deformation, thereby squeezing the gel in the first cavity and accordingly controlling the curvature change of the optical surface formed by the gel in the light-passing area, so that the variable focal length optical element may easily achieve a purpose of controlling optical zooming.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the invention as defined by the following claims. Moreover, no element and component in the disclosure is intended to be dedicated to the public regardless of whether the element or component is explicitly recited in the following claims.

What is claimed is:

1. A variable focal length optical element, comprising:
a light-transmitting layer;
a cover, having a first through hole to define a light-passing area, adhered to the light-transmitting layer via an adhesive layer, wherein the cover, the adhesive layer, and the light-transmitting layer surround and form a first cavity together;
a gel, filled in the first cavity;
a piezoelectric film; and
a driving electrode, configured to drive the piezoelectric film, wherein the driving electrode applies a driving voltage to the piezoelectric film, so that the piezoelectric film is stretched and deformed to pull the light-transmitting layer to bend and deform to squeeze the gel in the first cavity, and thereby controls a curvature change of an optical surface formed in the light-passing area by the gel protruding out from the first through hole.

2. The variable focal length optical element according to claim 1, wherein a material of the light-transmitting layer comprises a polymer material or glass.

3. The variable focal length optical element according to claim 1, wherein the light-transmitting layer is grown on the piezoelectric film by an epitaxial method.

4. The variable focal length optical element according to claim 1, wherein the light-transmitting layer is bonded to the piezoelectric film by an attaching method.

5. The variable focal length optical element according to claim 1, further comprising:
a first substrate, having a second through hole penetrating through the first substrate; and
a carrier layer, located on the first substrate, having a third through hole penetrating through the carrier layer, wherein the third through hole is formed by a protruding structure, the second through hole, the third through hole, and the first through hole are overlapped with each other, and a projection of the first through hole on the first substrate is completely located within projections of the second through hole and the third through hole on the first substrate, wherein the piezoelectric film is located on the carrier layer.

6. The variable focal length optical element according to claim 5, wherein the light-transmitting layer is located between the cover and the piezoelectric film.

7. The variable focal length optical element according to claim 6, wherein the carrier layer comprises:
a first insulating layer;
a second insulating layer, disposed in overlap with the first insulating layer; and
a wafer layer, located between the first insulating layer and the second insulating layer, wherein the piezoelectric film is disposed on the first insulating layer, and the light-transmitting layer is disposed on the piezoelectric film.

8. The variable focal length optical element according to claim 6, wherein the light-transmitting layer is a first insulating layer, the carrier layer comprises a second insulating layer and a wafer layer, the first insulating layer is stacked on the wafer layer, and the wafer layer is located between the second insulating layer and the light-transmitting layer.

9. The variable focal length optical element according to claim 6, wherein the carrier layer comprises a second insulating layer and a wafer layer, the second insulating layer is located between the first substrate and the wafer layer, the light-transmitting layer is located between the wafer layer and the piezoelectric film, and the piezoelectric film covers the light-passing area, wherein a material of the light-transmitting layer comprises a polymer material or glass.

10. The variable focal length optical element according to claim 5, wherein the piezoelectric film is located between the light-transmitting layer and the cover, and the first cavity comprises the first through hole of the cover and the third through hole of the carrier layer.

11. The variable focal length optical element according to claim 10, wherein the carrier layer comprises a first insulating layer and a wafer layer, the light-transmitting layer is a second insulating layer, the wafer layer is located between the first insulating layer and the light-transmitting layer, and the light-transmitting layer is located between the first substrate and the wafer layer, wherein the variable focal length optical element further comprises an auxiliary piezoelectric film, and the auxiliary piezoelectric film is disposed on the light-transmitting layer.

12. The variable focal length optical element according to claim 1, wherein the piezoelectric film has a fourth through hole, the piezoelectric film is located between the light-transmitting layer and the cover, and the first cavity comprises the first through hole of the cover and the fourth through hole of the piezoelectric film.

13. The variable focal length optical element according to claim 1, wherein the shape of the driving electrode is annular, and the driving electrode surrounds the light-passing area.

14. The variable focal length optical element according to claim 1, wherein the light-transmitting layer is disposed in overlap with the piezoelectric film.

15. The variable focal length optical element according to claim 1, wherein the light-transmitting layer and the piezoelectric film are arranged on a same plane.

16. The variable focal length optical element according to claim 5, wherein when the driving electrode causes the piezoelectric film to produce stretch deformation, the piezoelectric film pulls the light-transmitting layer to bend and deform via the protruding structure.

17. The variable focal length optical element according to claim 1, wherein when the driving electrode causes the piezoelectric film to produce stretch deformation, the piezoelectric film directly pulls the light-transmitting layer to bend and deform.
